(19) United States
(12) Patent Application Publication
(10) Pub. No.: US 2023/0176090 A1
(43) Pub. Date: Jun. 8, 2023

(54) MEASUREMENT PROBE AND METHOD

(71) Applicant: ROHDE & SCHWARZ GMBH & CO. KG, Munchen (DE)

(72) Inventor: Mario GUENTHER, Glauchau (DE)

(21) Appl. No.: 17/537,249

(22) Filed: Nov. 29, 2021

(51) Int. Cl. G01R 1/067

(52) U.S. Cl. CPC G01R 1/06788

(57) ABSTRACT

The present disclosure provides a measurement probe comprising a probe tip for contacting a device under test, a probe handle that accommodates the probe tip at least in part, an electrical interface for coupling the measurement probe to a measurement device, and a switch comprising a control input, a first load input that is electrically coupled to the probe tip and a second load input that is electrically coupled to the electrical interface, wherein in a closed state the switch electrically closes the connection between the probe tip and the electrical interface, and in an open state electrically interrupts the connection between the probe tip and the electrical interface. The present disclosure also provides a respective method.

### TECHNICAL FIELD

The disclosure relates to a measurement probe. In addition, the disclosure relates to a respective method.

### BACKGROUND

Although applicable to any kind of probe tips for any kind of measurement devices, the present disclosure will mainly be described in conjunction with probe tips for oscilloscopes.

When a user performs a measurement with an oscilloscope, the user needs to contact the device under test with a measurement probe that is electrically coupled to a measurement device like for example, an oscilloscope.

The measurement probe represents an ohmic and capacitive load for the device under test. Consequently, when performing a measurement the user needs to contact the device under test with the measurement probe and needs to remove the measurement probe to verify the functionality of the device under test. For performing a full measurement contacting and removing the measurement probe has to be performed multiple times.

Accordingly, there is a need for improving measurements in devices under test.

### SUMMARY

The above stated problem is solved by the features of the independent claims. It is understood, that independent claims of a claim category may be formed in analogy to the dependent claims of another claim category.

Accordingly, it is provided:

A measurement probe comprising a probe tip for contacting a device under test, a probe handle that accommodates the probe tip at least in part, an electrical interface for coupling the measurement probe to a measurement device, and a switch comprising a control input, a first load input that is electrically coupled to the probe tip and a second load input that is electrically coupled to the electrical interface, wherein in a closed state the switch electrically closes the connection between the probe tip and the electrical interface, and in an open state electrically interrupts the connection between the probe tip and the electrical interface.

Further, it is provided:

Method for measuring with a measurement probe, the method comprising providing a probe tip for contacting a device under test at least in part in a probe handle of the measurement probe, electrically coupling the measurement probe to a measurement device, and controlling a switch of the measurement probe that is electrically coupled between the probe tip and an electrical interface of the measurement probe, wherein in a closed state the switch electrically closes the connection between the probe tip and the electrical interface, and in an open state electrically interrupts the connection between the probe tip and the electrical interface.

When performing a measurement with a measurement probe in a device under test, also called DUT, the measurement probe needs to be placed by a user on the respective measurement point in the DUT. The moment the measurement probe is electrically in contact with the DUT, an ohmic and capacitive load will be presented to the circuitry of the DUT by the measurement probe, the connection between the measurement probe and the measurement device, and the measurement circuitry of the measurement device.

The user of the measurement probe may perform measurements. However, the user may also be required to remove the measurement probe from the DUT to verify the DUT’s functionality between consecutive measurements.

The present disclosure acknowledges the fact that most of the unwanted ohmic and capacitive load is presented by the signal path between the probe tip and the measurement circuitry in the measurement device.

The present disclosure therefore provides a measurement probe that allows interrupting the signal path in the measurement probe after the probe tip.

To this end, the measurement probe comprises a probe tip that serves for contacting the DUT and picking up the signals that are to be measured in the DUT. The signals are then transferred via the switch that may be provided in the probe handle, when the switch is in a closed state, to the electrical interface and from the electrical interface to a measurement device.

The switch comprises a first load input and a second load input, which serve for coupling the switch to the probe tip and to the electrical interface. The switch further comprises a control input for controllably closing or opening the switch.

As explained above, the probe tip alone only adds little ohmic and capacitive load on the DUT. By opening the switch i.e., controlling the switch to enter an opened state, the major cause of unwanted ohmic and capacitive load in the DUT is removed, even if the probe tip contacts the DUT.

Therefore, measurements may be performed with a closed switch, while further tests, like functional tests, may be performed in the DUT without removing the measurement probe but by opening the switch. It is understood, that the switch may be actuated independently of the state of the probe tip. The probe tip does for example not need to be in contact with the DUT to actuate the switch. The switch may therefore be closed or opened while the probe tip is not in contact with the DUT, or while the probe tip is in contact with the DUT.

A user of the measurement probe may therefore effectively perform sequences of measurements in a DUT. In addition, the user may position the probe tip without any electrical connection attached to the probe tip, and therefore with a reduced risk of causing a short circuit.

Further embodiments of the present disclosure are subject of the further dependent claims and of the following description, referring to the drawings.

In an embodiment, the switch may comprise a mechanically controlled switch.

The switch may comprise or be embodied as a mechanically controller switch. In such an embodiment, the probe handle may comprise a respective knob or button that may be mechanically coupled to the switch for controlling the switch.

With such a switch the control input may be a mechanical input that is mechanically actuated by a user via the respective knob or button on the probe handle.

In an embodiment, the user may push the knob or button to close the switch. Of course, a reverse logic may also be applied and the switch may be configured such that a user may push the button or knob to open the switch.

In another embodiment, the switch may comprise an electrically controlled switch.

The switch may instead of being a mechanically controlled switch also comprise or be provided as an electrically controlled switch. Such an electrically controlled switch may comprise e.g., a relay or another type of electrically controlled switch.

With an electrically controlled switch, the control signal provided to the control input is an electrical signal. Such a signal may be provided from different sources to the switch, and the switch may, therefore, be controlled very flexibly.

In a further embodiment, the switch may comprise a semiconductor switching element.

The switch may for example comprise a transistor like a bipolar transistor, a field-effect transistor, or a solid-state relay. Such a semiconductor switching element may easily be controlled from different sources.

Of course, the probe handle may comprise a knob or button that is electrically coupled to the control input of the switch and may be actuated by a user.

In another embodiment, the electrical interface may comprise a switching input that is electrically coupled to the control input.

The switching input as part of the electrical interface serves for receiving a switching signal from a measurement device that may be attached to the measurement probe.

With the switching input a measurement device may therefore control the switch. This allows implementing (semi-) automatic measurement sequences that comprise closing and opening the switch by the measurement device as required.

In yet another embodiment, the measurement probe may further comprise a controller, wherein the controller may be electrically coupled to the control input of the switch and may output a control signal to the control input. The controller may also be coupled to the switching input and receive the switching signal.

The controller may for example be coupled to a knob or button on the probe handle. The controller may therefore control the switch as if the knob or button was directly coupled to the switch. In such an embodiment, the controller may be seen as a kind of relay for the signal from the knob or button.

The controller may be provided as or comprise a dedicated processing element, like e.g. a processing unit, a microcontroller, an FPGA, a CPLD or the like. The controller may at least in part also be provided as a computer program product comprising computer readable instructions that may be executed by a processing element. In a further embodiment, the controller may be provided as addition or additional function or method to the firmware or operating system of a processing element that is already present in the respective application.

In addition, it is understood, that any required supporting or additional hardware may be provided like e.g., a power supply circuitry and clock generation circuitry.

In a further embodiment, the controller may comprise a switching logic that controls the switch.

The switching logic may perform any required processing steps prior to switching the switch to close the signal path of the probe tip.

In an embodiment, the switching logic may be electrically coupled to the probe tip and may control the switch based on a signal measured at the probe tip.

The switching logic may perform a measurement at the probe tip. Since the signal path is very short from the probe tip to the switching logic, the influence on the DUT is still low compared to the signal path from the probe tip to the measurement device.

The switching logic may for example identify that the probe tip is placed on the DUT based on the measured signals, and close the switch after detecting that the probe tip is placed on the DUT. Of course the switching logic may comprise a timer that delays the closing of the switch for a predefined amount of time. The switching logic may also close the switch only if the signal is present at the probe tip for more than a predetermined amount of time. The switching logic may also open the switch if the signal is not present at the probe tip any more.

Further, a second switch may be provided between the probe tip and the switching logic. The second switch may be used to open or interrupt the signal path between the probe tip and the switching logic, after the first switch is closed. This eliminates any adversarial effect that the switching logic may have on the measurement.

In yet another embodiment, the controller may be coupled with the electrical interface and may receive control signals via the electrical interface.

As already indicated above, the electrical interface may be coupled to a measurement device. With the controller being coupled to the electrical interface, the measurement device may therefore provide control signals to the controller.

The connection between the controller and the measurement device may for example comprise a digital interface, especially a serial or parallel data interface, like for example a RS-232 interface, or a USB interface. Any adequate protocol may be used to communicate data between the measurement device and the controller like for example a SCPI (Standard Commands for Programmable Instruments) protocol.

### BRIEF DESCRIPTION OF THE DRAWINGS

For a more complete understanding of the present disclosure and advantages thereof, reference is now made to the following description taken in conjunction with the accompanying drawings. The disclosure is explained in more detail below using exemplary embodiments which are specified in the schematic figures of the drawings, in which:

FIG. 1 shows a block diagram of an embodiment of a measurement probe according to the present disclosure;

FIG. 2 shows a block diagram of another embodiment of a measurement probe according to the present disclosure;

FIG. 3 shows a block diagram of a further embodiment of a measurement probe according to the present disclosure;

FIG. 4 shows a block diagram of another embodiment of a measurement probe according to the present disclosure; and

FIG. 5 shows a flow diagram of an embodiment of a method according to the present disclosure.

In the figures like reference signs denote like elements unless stated otherwise.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

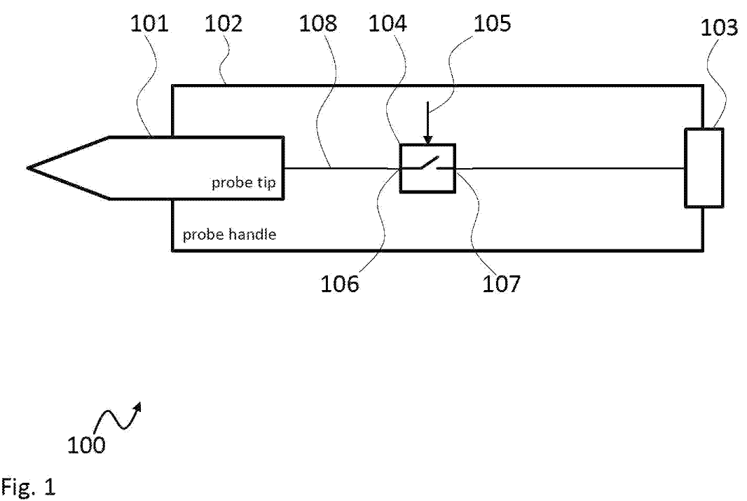

FIG. 1 shows a block diagram of a measurement probe 100. The measurement probe 100 comprises a probe tip 101 that is accommodated in a probe handle 102 such that at least the front tip of the probe tip 101 protrudes from the probe handle 102. The measurement probe 100 further comprises an electrical interface 103 and a switch 104. The probe tip 101 is coupled to a first load input 106 of the switch 104. The electrical interface 103 is coupled to a second load input 107 of the switch 104.

The electrical interface 103 serves for coupling the measurement probe 100 to a measurement device like e.g., an oscilloscope or any other measurement device.

The probe tip 101 serves for electrically contacting a device under test (not shown), DUT, and picking up signals that are to be measured in the DUT. The signals that are picked-up by the probe tip 101 are provided to the switch 104.

In a closed state of the switch 104, the signals are forwarded to the electrical interface 103 and from there to the measurement device. However, in an open state of the switch, the signal path is interrupted in the switch, and the signals are not forwarded.

In the open state of the switch 104, the signal path ends in the switch 104. Therefore, the signal path only provides little of the unwanted ohmic and capacitive load. The switch 104 may be positioned as near as possible to the probe tip 101 in the probe handle 102. This reduces the length of the signal path in the open state of the switch 104, and therefore, also reduces the unwanted ohmic and capacitive load in the DUT.

The electrical interface 103 may comprise a connector for coupling the measurement probe 100 electrically and mechanically to a measurement device via a cable. Such a connector may comprise contacts for transmitting the signal that is measured in the DUT. In addition, such a connector may comprise additional contacts for transmitting further signals from the measurement probe 100 to the measurement device or from the measurement device to the measurement probe 100.

Although not explicitly shown, it is understood, that the probe handle 102 may comprise any adequate exterior shape or form that allows holding the probe handle 102.

The switch 104 comprises a control input 105 that serves for controlling the switch with an external source. This external source may control the switch 104 independently of the state of the probe tip 101, and especially the contacting state between the probe tip 101 and the DUT.

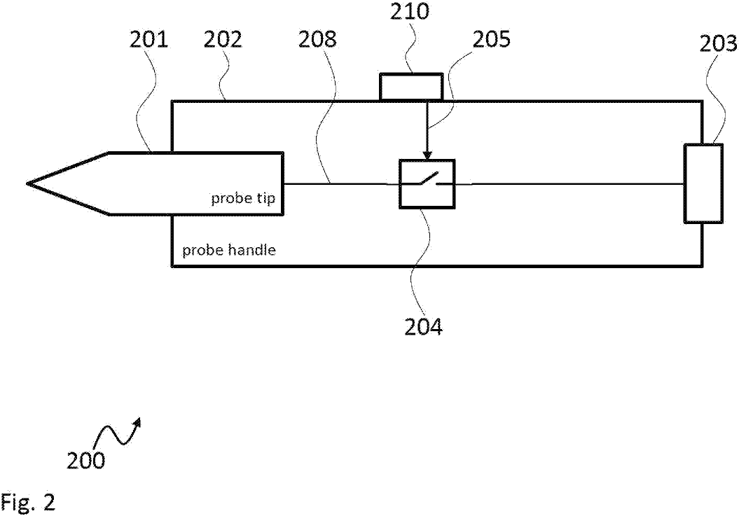

FIG. 2 shows a block diagram of a measurement probe 200. The measurement probe 200 is based on measurement probe 100. Therefore, the measurement probe 200 comprises a probe tip 201 that is accommodated in a probe handle 202 such that at least the front tip of the probe tip 201 protrudes from the probe handle 202. The measurement probe 200 further comprises an electrical interface 203 and a switch 204. The probe tip 201 is coupled to a first load input of the switch 204. The electrical interface 203 is coupled to a second load input of the switch 204.

The switch 204 is provided as a mechanical switch, and the control input 205 of the switch 204 is a mechanical input. The measurement probe 200 further comprises a mechanical button or knob 210 on the probe handle 202 that is mechanically coupled to the switch 204.

When a user pushes the button or knob 210, the switch 204 is closed and a signal path between the probe tip 201 and the electrical interface 203 is established e.g., for performing a measurement. The button or knob 210 may be of a type that holds its state like for example a slide switch. As alternative, the button or knob 210 may be of a type that returns to the original state when the user releases the button or knob 210.

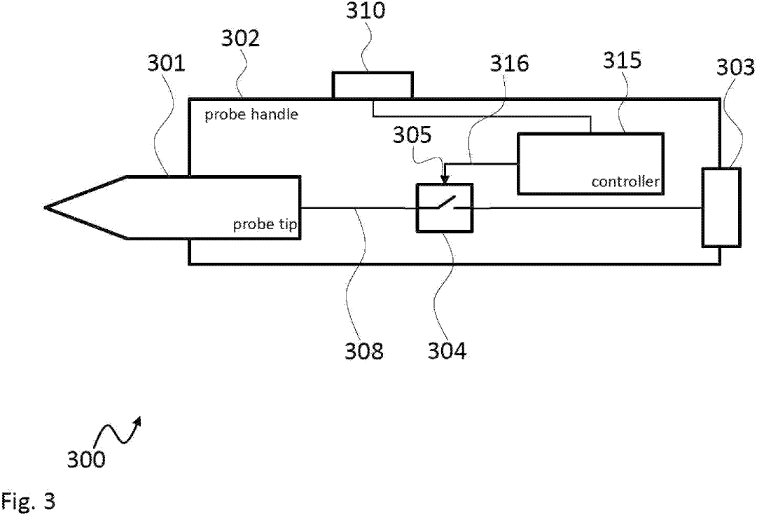

FIG. 3 shows a block diagram of a measurement probe 300. The measurement probe 300 is based on the measurement probe 200. Therefore, the measurement probe 300 comprises a probe tip 301 that is accommodated in a probe handle 302 such that at least the front tip of the probe tip 301 protrudes from the probe handle 302. The measurement probe 300 further comprises an electrical interface 303 and a switch 304. The probe tip 301 is coupled to a first load input of the switch 304. The electrical interface 303 is coupled to a second load input of the switch 304. The measurement probe 300 also comprises a button or knob 310.

The button or knob 310 of the measurement probe 300 is coupled to a controller 315 that is provided in the measurement probe 300. The controller 315 is further coupled to the control input 305 of the switch 304.

In the measurement probe 300 the switch 304 is provided as an electronic switching element that may be electronically controlled like e.g., a relay or a semiconductor switch.

The controller 315 may be a simple circuit that generates the required type of control signal 316 from the signal provided by the switch 304. Such a circuit may comprise passive components like resistors. The controller may also comprise an active logic device, like a configurable logic device or programmable logic device. Such devices may comprise but are not limited to CPLDs, FPGAs, microcontrollers, microprocessors, and processors.

An active logic device may for example provide additional functionality like error monitoring, signaling, and communication with the measurement device.

The controller 315 may for example perform a debouncing of the button or knob 310, if the button or knob 310 is a pushbutton-type input.

The error monitoring may comprise verifying the correct functionality of the button or knob 310. If the button or knob 310 is of the type that returns to an open state after being released, the controller 315 may verify if the button or knob 310 ever returns to the open state or not. If the button or knob 310 does not return to the open state, the button or knob 310 may be blocked or defective. The controller 315 may signal this for example with an optical signal like a red flashing LED or may provide a respective signal to the measurement device via the electrical interface 303.

The controller 315 may also verify the correct functionality of the switch 304 and verify that the switch 304 opens or closes as indicated by the control signal 316. To this end, the control signal 316 may comprise a further connection to the signal path between the probe tip 301, the switch 304, and the electrical interface 303.

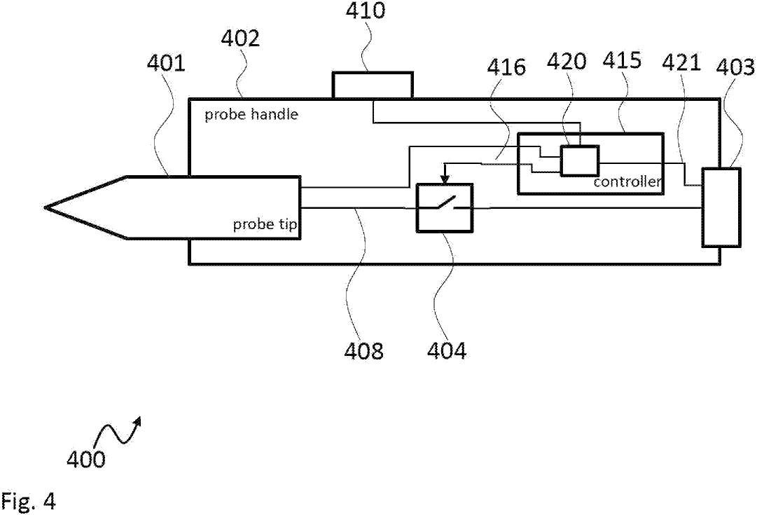

FIG. 4 shows a block diagram of a measurement probe 400. The measurement probe 400 is based on the measurement probe 300. Therefore, the measurement probe 400 comprises a probe tip 401 that is accommodated in a probe handle 402 such that at least the front tip of the probe tip 401 protrudes from the probe handle 402. The measurement probe 400 further comprises an electrical interface 403 and a switch 404. The probe tip 401 is coupled to a first load input of the switch 404. The electrical interface 403 is coupled to a second load input of the switch 404. The measurement probe 400 also comprises a button or knob 410.

The button or knob 410 of the measurement probe 400 is coupled to a controller 415 that is provided in the measurement probe 400. The controller 415 is further coupled to the control input of the switch 404. The above-presented explanations regarding the controller 315 apply to the controller 415 mutatis mutandis.

The controller 415 comprises a switching logic 420 that generates the control signal 416. The switching logic 420 is coupled to the button or knob 410, to the probe tip 401, and to the electrical interface 403. It is understood, that the switching logic 420 may in other embodiments be coupled only to one or two of the button or knob 410, the probe tip 401, and the electrical interface 403.

The switching logic 420 may receive a signal from the button or knob 410 and generate a control signal 416 accordingly.

The switching logic 420 may also receive a signal from the measurement device via the switching input 421 and the electrical interface 403, and generate a respective control signal 416. Such a switching input 421 may comprise a discrete digital signal or may be based on any adequate protocol e.g., the SCPI protocol.

The switching logic 420 may also perform a measurement of signals at the probe tip 401, and generate a control signal 416 to close the switch 404 if signals are present at the probe tip 401.

Of course, the switching logic 420 may perform logical operations on the single input signals and for example only output a control signal 416 to close the switching logic 420 if multiple of the input signals comprise the respective values.

The switching logic 420 may for example only generate a control signal 416 to close the switch 404 if a general clearance is received from the measurement device, or if the button or knob 410 is actuated by a user and at the same time a signal is present at the probe tip 401, or if the button or knob 410 is actuated and the measurement device requests a measurement.

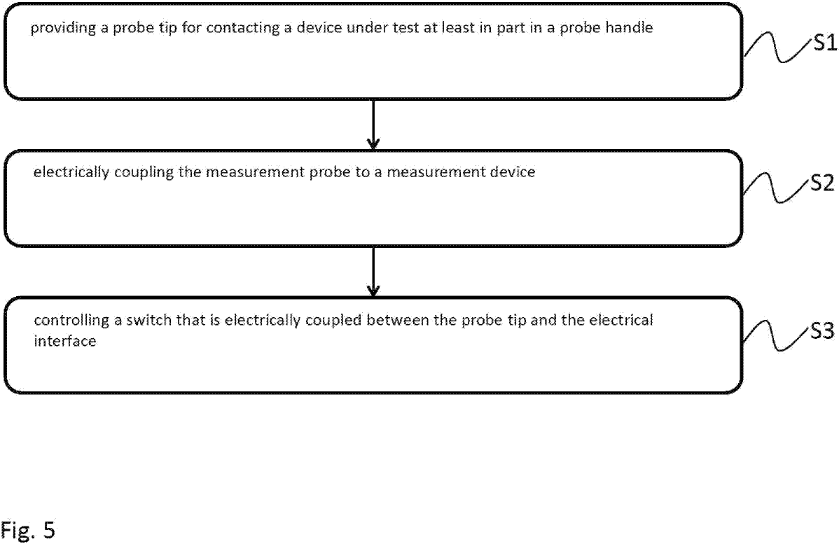

For sake of clarity in the following description of the method-based FIG. 5 the reference signs used above in the description of apparatus-based FIGS. 1-4 will be maintained.

FIG. 5 shows a flow diagram of a method for measuring with a measurement probe 100, 200, 300, 400.

The method comprises providing a probe tip 101, 201, 301, 401 for contacting a device under test at least in part in a probe handle 102, 202, 302, 402, electrically coupling the measurement probe 100, 200, 300, 400 to a measurement device, and controlling a switch 104, 204, 304, 404 that is electrically coupled between the probe tip 101, 201, 301, 401 and an electrical interface 103, 203, 303, 403 of the measurement probe 100, 200, 300, 400. In a closed state the switch 104, 204, 304, 404 electrically closes the connection between the probe tip 101, 201, 301, 401 and the electrical interface 103, 203, 303, 403, and in an open state electrically interrupts the connection between the probe tip 101, 201, 301, 401 and the electrical interface 103, 203, 303, 403.

The switch 104, 204, 304, 404 may for example be mechanically controlled.

As alternative, the switch 104, 204, 304, 404 may be electrically controlled. Such a switch 104, 204, 304, 404 may comprise a semiconductor switching element. The electrical interface 103, 203, 303, 403 may comprise a switching input that is electrically coupled to the control input 105, 205, 305 of the switch 104, 204, 304, 404 and may receive control signals 416 for the switch 104, 204, 304, 404.

The method may further comprise outputting a control signal 416 to the control input 105, 205, 305 of the switch 104, 204, 304, 404 from a controller. The control signal 416 may be provided from a switching logic in the controller.

The switching logic may be electrically coupled to the probe tip 101, 201, 301, 401 and may control the switch 104, 204, 304, 404 based on a signal measured at the probe tip 101, 201, 301, 401.

The controller may be coupled with the electrical interface 103, 203, 303, 403 and may receive control signals 416 via the electrical interface 103, 203, 303, 403. The switching logic may control the switch 104, 204, 304, 404 based on the control signal 416.

Although specific embodiments have been illustrated and described herein, it will be appreciated by those of ordinary skill in the art that a variety of alternate and/or equivalent implementations exist. It should be appreciated that the exemplary embodiment or exemplary embodiments are only examples, and are not intended to limit the scope, applicability, or configuration in any way. Rather, the foregoing summary and detailed description will provide those skilled in the art with a convenient road map for implementing at least one exemplary embodiment, it being understood that various changes may be made in the function and arrangement of elements described in an exemplary embodiment without departing from the scope as set forth in the appended claims and their legal equivalents. Generally, this application is intended to cover any adaptations or variations of the specific embodiments discussed herein.

LIST OF REFERNCE SIGNS

| | |
|---|---|
| 100, 200, 300, 400 | measurement probe |
| 101, 201, 301, 401 | probe tip |
| 102, 202, 302, 402 | probe handle |
| 103, 203, 303, 403 | electrical interface |
| 104,204,304,404 | switch |
| 105, 205, 305 | control input |
| 106 | first load input |
| 107 | second load input |
| 108, 208, 308, 408 | measured signal |
| 210,310,410 | knob |
| 315,415 | controller |
| 316, 416 | control signal |
| 420 | switching logic |
| 421 | switching input |

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A measurement probe comprising:
a probe tip for contacting a device under test;
a probe handle that accommodates the probe tip at least in part;
an electrical interface for coupling the measurement probe to a measurement device; and
a switch comprising a control input, a first load input that is electrically coupled to the probe tip and a second load input that is electrically coupled to the electrical interface,
wherein in a closed state the switch electrically closes a connection between the probe tip and the electrical interface, and in an open state electrically interrupts the connection between the probe tip and the electrical interface.

2. The measurement probe according to claim 1, wherein the switch comprises a mechanically controlled switch.

3. The measurement probe according to claim 1, wherein the switch comprises an electrically controlled switch.

4. The measurement probe according to claim 3, wherein the switch comprises a semiconductor switching element.

5. The measurement probe according to claim 3, wherein the electrical interface comprises a switching input that is electrically coupled to the control input.

6. The measurement probe according to claim 3, further comprising a controller,
wherein the controller is electrically coupled to the control input of the switch and outputs a control signal to the control input.

7. The measurement probe according to claim 6, wherein the controller comprises a switching logic that controls the switch.

8. The measurement probe according to claim 7, wherein the switching logic is electrically coupled to the probe tip and controls the switch based on a signal measured at the probe tip.

9. The measurement probe according to claim 6, wherein the controller is coupled with the electrical interface and receives control signals via the electrical interface.

10. A method for measuring with a measurement probe, the method comprising:
providing a probe tip for contacting a device under test at least in part in a probe handle of the measurement probe;
electrically coupling the measurement probe to a measurement device; and
controlling a switch that is electrically coupled between the probe tip and an electrical interface of the measurement probe, wherein in a closed state the switch electrically closes a connection between the probe tip and the electrical interface, and in an open state electrically interrupts the connection between the probe tip and the electrical interface.

11. The method according to claim 10, wherein the switch is mechanically controlled.

12. The method according to claim 10, wherein the switch is electrically controlled.

13. The method according to claim 12, wherein the switch comprises a semiconductor switching element.

14. The method according to claim 12, wherein the electrical interface comprises a switching input that is electrically coupled to a control input of the switch and that receives control signals for the switch.

15. The method according to claim 12, further comprising:
outputting a control signal to a control input of the switch from a controller.

16. The method according to claim 15, wherein the control signal is provided from a switching logic in the controller.

17. The method according to claim 16, wherein the switching logic is electrically coupled to the probe tip and controls the switch based on a signal measured at the probe tip.

18. The method according to claim 15, wherein the controller is coupled with the electrical interface and receives control signals via the electrical interface.
